(19) United States
(12) Patent Application Publication
(10) Pub. No.: US 2008/0068794 A1
(43) Pub. Date: Mar. 20, 2008

(54) DISSIPATION MODULE AND ELECTRONIC DEVICE HAVING THE SAME

(75) Inventors: Chien-Che Ting, Taipei (TW); Pai-I Yang, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: AMA PRECISION INC., Taipei (TW)

(21) Appl. No.: 11/858,134

(22) Filed: Sep. 20, 2007

(30) Foreign Application Priority Data
Sep. 20, 2006 (TW) 95134759

(51) Int. Cl. H05K 7/20

(52) U.S. Cl. 361/692; 361/697; 361/702

(57) ABSTRACT

A heat dissipation module including a fins-assembly and a fixing frame is provided. The fins-assembly has at least an air outlet. The fixing frame has at least three fixing posts. The fins-assembly is disposed between the fixing posts. In addition, the heat dissipation module is obliquely disposed on a heat source of an electronic device.

### CROSS-REFERENCE TO RELATED APPLICATION

This application claims the priority benefit of Taiwan application serial no. 95134759, filed Sep. 20, 2006. All disclosure of the Taiwan application is incorporated herein by reference.

### BACKGROUND OF THE INVENTION

1. Field of the Invention

The present invention relates to a heat dissipation module, and more particularly, to a heat dissipation module disposed on an electronic device.

2. Description of Related Art

In recent years, the rapid development of electronic technologies have lead to a sustained increase in the operating speed of the electronic component (for example, the CPU) of an electronic device. With the ever-increasing operating speed, the thermal rating of the electronic component also rises accordingly. To prevent the electronic component in the electronic device from overheating leading to a temporary or permanent failure of the entire electronic device, a heat dissipation module must be disposed on the heat source (the electronic component) of the electronic device. The heat dissipation module lowers the working temperature of the heat source so that the electronic device is able to operate normally.

FIG. 1 is a perspective view of a conventional heat dissipation module disposed on the heat source of an electronic device. As shown in FIG. 1, the conventional heat dissipation module 100 mainly comprises a bottom plate 110, a fins-assembly 120, at least one heat pipe 130 and a fan 140. In the conventional technique, a surface of the bottom plate 110 is suitable for contacting the heat source 12 on the electronic device 10 and the fins-assembly 120 is disposed on another surface of the bottom plate 110. The heat pipe 130 is disposed between the fins-assembly 120 and the bottom plate 110. In addition, the fan is disposed above the fins-assembly 120.

It should be noted that a number of electronic components 14 (for example, capacitors or inductors) are normally disposed around the heat source 12 of the electronic device 10. Furthermore, the conventional heat dissipation module 100 is directly disposed on the heat source 12 according to the direction of assembly (the alignment direction L1 of the fins-assembly is perpendicular or parallel to any one side of the heat source 12). Therefore, when the heat dissipation module 100 is assembled onto the heat source 12, the heat dissipation module 100 may interfere with the electronic components 14 surrounding the heat source 12 and lead to some difficulties in the assembling process.

### SUMMARY OF THE INVENTION

Accordingly, at least one objective of the present invention is to provide a heat dissipation module suitable for mounting over the heat source inside an electronic device.

At least another objective of the present invention is to provide a heat dissipation module that can effectively lower the working temperature inside an electronic device.

To achieve these and other advantages and in accordance with the purpose of the invention, as embodied and broadly described herein, the invention provides a heat dissipation module including a fins-assembly and a fixing frame. The fins-assembly has at least an air outlet. The fixing frame has at least three fixing posts. The fins-assembly is disposed between the fixing posts and the fixing posts are located in the air outlet.

In one embodiment of the present invention, the foregoing fixing frame includes a frame body and a plurality of fixing posts extending out of the frame body.

In one embodiment of the present invention, the foregoing frame body has a space whose spatial dimension corresponds to the size of the fins-assembly.

In one embodiment of the present invention, the foregoing heat dissipation module further includes a bottom plate, and the fins-assembly is disposed on the bottom plate.

In one embodiment of the present invention, the foregoing heat dissipation module further includes at least one heat pipe disposed between the bottom plate and the fins-assembly.

In one embodiment of the present invention, the foregoing fins-assembly has two air outlets.

In one embodiment of the present invention, the foregoing fins-assembly has four air outlets.

In one embodiment of the present invention, the foregoing heat dissipation module further includes a fan disposed on the fixing frame.

The present invention also provides an electronic device comprising a circuit board and the foregoing heat dissipation module. The circuit board has at least one heat source and the heat dissipation module is disposed on the heat source. The bottom plate has a first surface and a second surface. The first surface of the bottom plate is suitable for contacting the heat source and the fins-assembly of the heat dissipation module is disposed on the second surface of the bottom plate. The fins-assembly has a plurality of fins and the fins are disposed on the second surface along an arranged direction. Furthermore, the arranged direction of the fins forms an angle with one side of the heat source. The angle is between 15° to 75°. In addition, the fixing frame is assembled on the fins-assembly so that the fins-assembly and the bottom plate are combined and positioned on the heat source.

In the present invention, the heat dissipation module is disposed on the heat source of the electronic device obliquely (the arranged direction of the fins is not perpendicular or parallel to any one side of the heat source) so that the heat dissipation module can be smoothly mounted over the heat source. In addition, a fixing frame having at least three fixing posts is mounted on the fins-assembly so that the fins-assembly and the bottom plate are firmly disposed on the heat source. The fins-assembly is disposed between the fixing posts and the fixing posts are located in the air outlet. Moreover, the fan disposed on the fixing frame can generate an active airflow. The active airflow flows through the fins-assembly and exits from the air outlet on a side of the fins-assembly so that the heat produced by other heat sources disposed on the circuit board is also carried away. Thus, the working temperature inside the electronic device is lowered.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a perspective view of a conventional heat dissipation module disposed on the heat source of an electronic device.

FIG. 2 is a perspective view of an electronic device according to one preferred embodiment of the present invention.

FIG. 3 is an exploded view showing all the components of the heat dissipation module in FIG. 2.

FIG. 4 is a diagram of another fixing frame according to one preferred embodiment of the present invention.

FIG. 5 is a bottom view showing the heat dissipation module of FIG. 2 disposed on a heat source.

FIG. 6 is a perspective view showing another fins-assembly according to one preferred embodiment of the present invention.

FIG. 7 is a diagram showing the combination of the fins-assembly of FIG. 2 and a bottom plate after the addition of heat pipes.

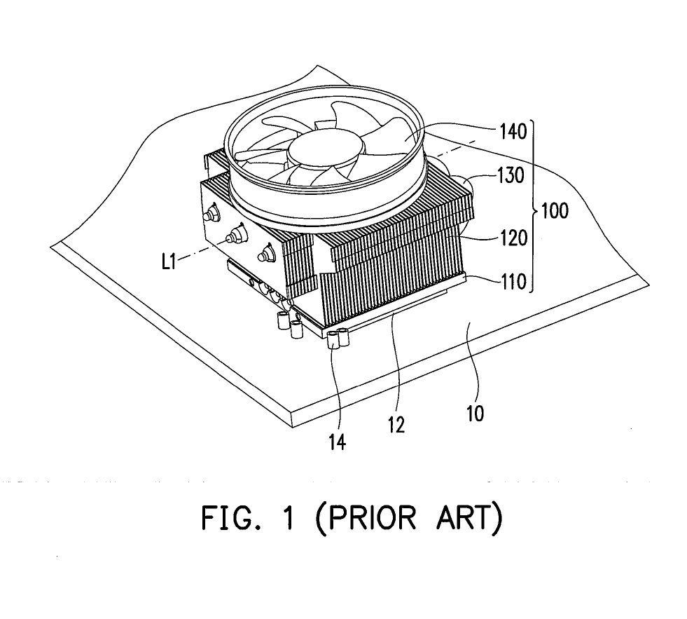

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

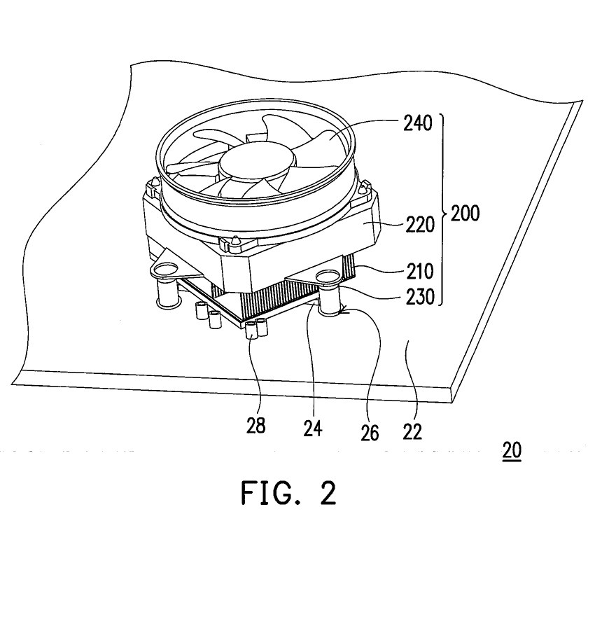

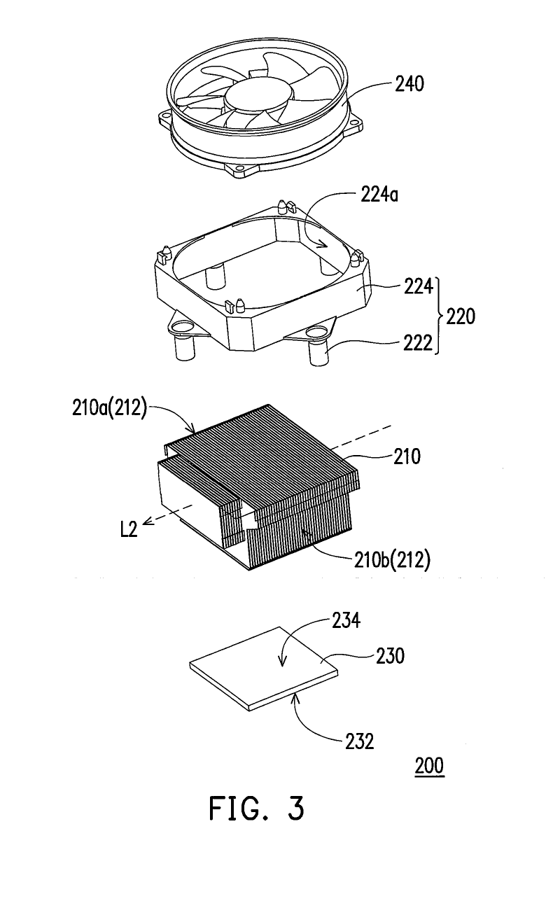

FIG. 2 is a perspective view of an electronic device according to one preferred embodiment of the present invention. FIG. 3 is an exploded view showing all the components of the heat dissipation module in FIG. 2. As shown in FIGS. 2 and 3, the electronic device 20 in the present embodiment mainly includes a circuit board 22 and a heat dissipation module 200. The circuit board 22 has a heat source 24 and the heat dissipation module 200 is disposed on the heat source 24. The heat dissipation module 200 in the present embodiment includes a fins-assembly 210 and a fixing frame 220. The fins-assembly 210 comprises a plurality of fins and the fins are disposed on a second surface 234 of a bottom plate 230 and arranged along a direction L2. A first surface 232 of the bottom plate 230 is suitable for contacting the heat source 23. The foregoing fins-assembly 210 and the bottom plate 230 can be fabricated using copper, aluminum or other suitable metallic material. In addition, in one embodiment, the fins-assembly 210 and the bottom plate 230 may be integrally formed.

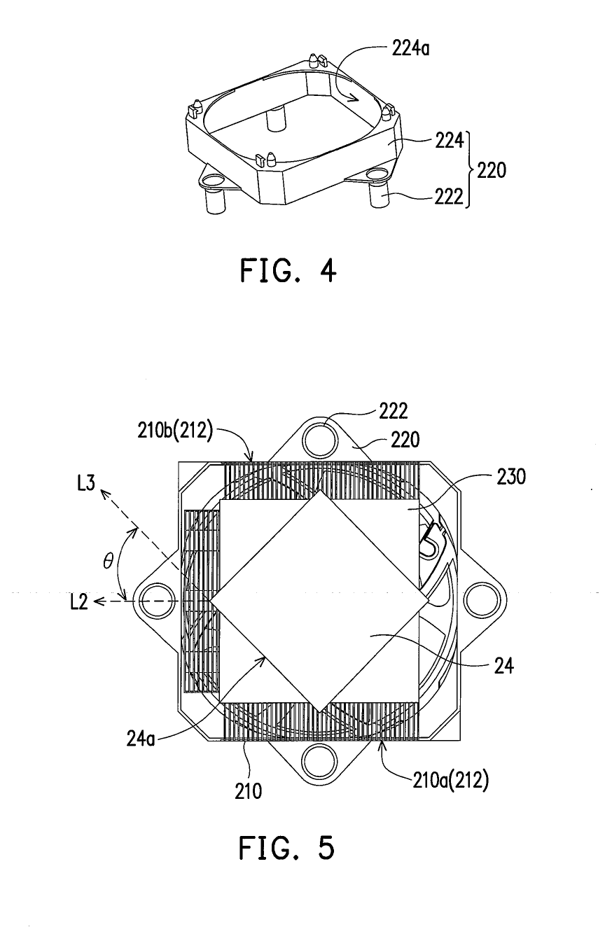

Accordingly, the fixing frame 220 in the present embodiment is mounted on the fins-assembly 210. The fixing frame 220 has three or more fixing posts 222 (four are shown in the present embodiment). These fixing posts 222, for example, extend from the frame body 224 of the fixing frame 220, and the fins-assembly 210 is disposed between the fixing posts 222. In one preferred embodiment, the frame body 210 has a space 224a having a spatial dimension corresponding to the size of the fins-assembly 210 so that the fixing frame 220 can snugly slide into the top portion of the fins-assembly 210. In addition, the fixing frame 220 can be connected to the heat dissipation module fixing holes 26 surrounding the heat source 24 through a plurality of locking elements (not shown) so that the combination of the fins-assembly 210 and the bottom plate 230 are firmly assembled on the heat source 24. Because the purpose of the fixing frame 220 is to assemble the fins-assembly 210 and the bottom plate 230 firmly together over the heat source 24, the number of fixing posts 222 in the present invention is not fixed. FIG. 4 is a diagram of another fixing frame according to one preferred embodiment of the present invention. In this preferred embodiment, the fixing frame 220 has three fixing posts 222, and the combination of the fins-assembly 210 and the bottom plate 230 is able to firmly mount on top of the heat source 24 through the three fixing posts 222. Obviously, the number of fixing posts 222 in the fixing frame 220 is set according to the number of heat dissipation module holes 26 surrounding the heat source 24.

As shown in FIGS. 2 and 3, the present embodiment also allows the installation of a fan 240 on the fixing frame 220. The fan 240 generates a convectional airflow to dissipate the heat from the fins-assembly 210 or the bottom plate 230 and lower the temperature of the heat source 24. The convectional airflow produced by the fan 240 flows through the fins-assembly 210 and exits between the fins-assembly 210 through the air outlet 212. More specifically, in the fins-assembly 210 of the present embodiment, the fins-assembly 210 comprises a plurality of fins with a gap there-between. Therefore, the convectional airflow produced by the fan 240 will flow out via the gaps between the fins. In other words, in the present embodiment, the two sides 210a and 210b of the fins-assembly 210 serves as the air outlets 212 of the convectional airflow, and the foregoing fixing posts 222 are located in the air outlets 212.

To prevent the heat dissipation module 200 from interfering with the electronic components 28 (for example, the capacitors or inductors) surrounding the heat source 24 in the assembling process, the heat dissipation module 200 in the present embodiment is obliquely disposed on the heat source 24 of the electronic device 20. More specifically, the direction L2 of the fins in the heat dissipation module 200 forms an included angle θ with the extending direction L3 of one side 24a of the heat source 24. The angle θ is between 15° to 75° (refer to FIG. 5, a bottom view showing the heat dissipation module of FIG. 2 disposed on a heat source). Hence, the heat dissipation module 200 can steer clear of the interference of the electronic components 28 and be smoothly disposed on the heat source 24.

In addition, because the heat dissipation module 200 has no restriction on the assembling direction (the heat dissipation module can be disposed on the heat source 24 obliquely), the direction of the heat dissipation module 200 on the heat source 24 adjusted according to the heat dissipating requirements inside the electronic device 20. As a result, the air outlet 212 of the fins-assembly 210 is able to face those heat-generating components (for example, the memory module) inside the electronic device 20. After the convectional airflow produced by the fan 240 exits from the air outlet 212, it may flow over other heat-generating components to carry away some of the heat from these heat-generating components and lower the internal temperature of the electronic device 20. In other embodiments, the fins-assembly 210 may also have four air outlets 212 (refer to FIG. 6, a perspective view showing another fins-assembly according to one preferred embodiment of the present invention). Hence, the active airflow flowing out from these air outlets 212 has a greater capacity to dissipate the heat from the heat-generating components surrounding the fins-assembly 210 and significantly lower the internal temperature of the electronic device 20.

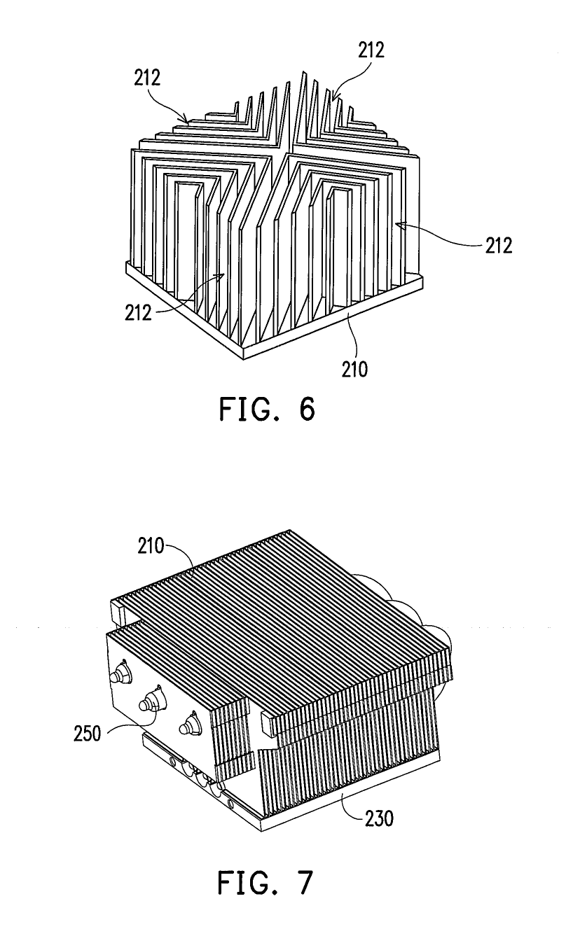

In another embodiment, the heat dissipation module 200 may include one or more heat pipes 250 (refer to FIG. 7, a diagram showing the combination of the fins-assembly of FIG. 2 and a bottom plate after the addition of heat pipes) disposed between the bottom plate 230 and the fins-assembly 210. The heat pipe 250 can effectively transfer the heat generated by the heat source 24 to the fins-assembly 210 and the heat-dissipation module 200 can dissipate the heat generated by the heat source 24 through a convective current set up between the fins-assembly 210 and the environment.

In summary, the heat dissipation module is obliquely disposed on the heat source of the electronic device (the included angle between the direction of the fins and an extending direction one side of the heat source is between 15° to 75°) so that interference with the electronic components surrounding the heat source in the process of assembling the heat dissipation module to the heat source is minimized. In other words, the heat dissipation module can be smoothly mounted over the heat source. In addition, a fixing frame having at least three fixing posts is mounted on the fins-assembly so that the fins-assembly and the bottom plate are firmly assembled and disposed on the heat source. The fins-assembly is disposed between the fixing posts and the fixing posts are located in the air outlet. Moreover, the direction of the heat dissipation module on the heat source may be adjusted according to the heat dissipating requirements inside the electronic device so that the air outlet of the fins-assembly is able to face those heat-generating components of the electronic device that generate heat. As a result, the convectional airflow produced by the fan may flow over the heat-generating components after exiting from the air outlet and carry some of the heat away. Thus, the electronic device is able to maintain a normal working temperature and operate normally at all times.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A heat dissipation module, comprising:
a fins-assembly, having at least one air outlet; and
a fixing frame, having at least three fixing posts, wherein the fins-assembly disposed between the fixing posts located in the air outlets.

2. The heat dissipation module of claim 1, wherein the fixing frame comprises a frame body and the fixing posts extends from the frame body.

3. The heat dissipation module of claim 2, wherein the frame body has a space with a spatial dimension that corresponds to a size of the fins-assembly.

4. The heat dissipation module of claim 1, further comprising a bottom plate wherein the fins-assembly is disposed on a bottom plate.

5. The heat dissipation module of claim 4, further comprising at least one heat pipe disposed between the bottom plate and the fins-assembly.

6. The heat dissipation module of claim 1, wherein the fins-assembly has two air outlets.

7. The heat dissipation module of claim 1, wherein the fins-assembly has four air outlets.

8. The heat dissipation module of claim 1, further comprising a fan disposed on the fixing frame.

9. An electronic device, comprising:
a circuit board, having at least one heat source;
a heat dissipation module, disposed on the heat source, the heat dissipation module comprising:
a bottom plate, having a first surface and a second surface, wherein the first surface of the bottom plate contacts the heat source; and
a fins-assembly, having a plurality of fins arranged along a direction and disposed on the second surface of the bottom plate, wherein the direction of the fins forms an included angle with one side of the heat source, and wherein the included angle is between 15° to 75°.

10. The electronic device of claim 9, further comprising a fixing frame assembled with the fins-assembly for mounting assembled fins-assembly and the bottom plate on the heat source.

11. The electronic device of claim 10, wherein the fins-assembly has at least one air outlet, the fixing frame has at least three fixing posts, and the fins-assembly is disposed between the fixing posts.

12. The electronic device of claim 11, wherein the fixing frame comprises a frame body and the fixing posts extend from the frame body.

13. The electronic device of claim 12, wherein the frame body has a space with a spatial dimension that corresponds to a size of the fins-assembly.

14. The electronic device of claim 9, wherein the fins-assembly has two air outlets.

15. The electronic device of claim 9, wherein the fins-assembly has four air outlets.

16. The electronic device of claim 9, wherein the heat dissipation module further comprises at least one heat pipe disposed between the bottom plate and the fins-assembly.

17. The electronic device of claim 10, wherein the heat dissipation module further comprises a fan disposed over the fixing frame.
